(19) United States
(12) Patent Application Publication
(10) Pub. No.: US 2026/0244099 A1
(43) Pub. Date: Aug. 20, 2026

(54) ENHANCED EUV PHOTORESISTS AND METHODS OF THEIR USE

(71) Applicants: Alex P. G. Robinson, Birmingham (GB); Edward Jackson, Franklin, MA (US); John Roth, Cohasset, MA (US); Tom Lada, Somerville, MA (US); Greg O'Callaghan, Worcestershire (GB)

(72) Inventors: Alex P. G. Robinson, Birmingham (GB); Edward Jackson, Franklin, MA (US); John Roth, Cohasset, MA (US); Tom Lada, Somerville, MA (US); Greg O'Callaghan, Worcestershire (GB)

(73) Assignee: Irresistible Materials LTD, Birmingham, EN (GB)

(21) Appl. No.: 18/874,489

(22) PCT Filed: Jul. 5, 2022
(86) PCT No.: PCT/US2022/036121

§ 371 Date: Dec. 12, 2024

Related U.S. Application Data
(60) Provisional application No. 63/218,351, filed on Jul. 4, 2021.

(51) Int. Cl. G03F 7/029

(52) U.S. Cl. CPC G03F 7/029

(57) ABSTRACT

The present application for patent discloses a composition of matter comprising a solvent; and an ester having a chemical structure chosen from (I):
wherein X and Y are the same or different, wherein X, Y and R₁-R₄ and are branched or unbranched, substituted or unsubstituted alkyl chains of 1-24 carbon atoms having 0-16 heteroatoms substituted into the chain, are substituted or unsubstituted phenyl groups, heteroaromatic groups, or fused aromatic or fused heteroaromatic groups or combinations of both.

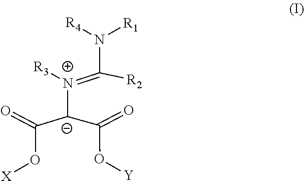

### REFERENCE TO PRIOR FILED APPLICATIONS

The present application is a continuation-in-part, and claims the benefit under 35 U.S.C. § 120, of U.S. Patent Application Ser. No. 63/218,351, filed on 4 Jul. 2021, entitled “Enhanced EUV Photoresists and Methods of Their Use,” which application is incorporated by reference herein in their entirety.

### FIELD OF THE INVENTION

The present application for patent is in the field of nanolithography materials and more specifically is in the field of molecular glass photoresists containing zwitterionic materials, their formulation and their use.

### BACKGROUND

As is well known, the manufacturing process of various kinds of electronic or semiconductor devices such as ICs, LSIs and the like involves fine patterning of a resist layer on the surface of a substrate material such as a semiconductor silicon wafer. This fine patterning process has traditionally been conducted by the photolithographic method in which the substrate surface is uniformly coated with a positive or negative tone photosensitive composition to form a thin layer and selectively irradiating with actinic rays (such as ultraviolet (UV), deep UV, vacuum UV, extreme UV, x-rays, electron beams and ion beams) via a transmission or reflecting mask followed by a development treatment to selectively dissolve away the coated photosensitive layer in the areas exposed or unexposed, respectively, to the actinic rays leaving a patterned resist layer on the substrate surface. The patterned resist layer, thus obtained, may be utilized as a mask in the subsequent treatment on the substrate surface such as etching. The fabrication of structure with dimensions of the order of nanometers is an area of considerable interest since it enables the realization of electronic and optical devices which exploit novel phenomena such as quantum confinement effects and also allows greater component packing density. As a result, the resist pattern is required to have an ever-increasing fineness which can be accomplished by using actinic rays having a shorter wavelength than the conventional ultraviolet light. Accordingly, it is now the case that, in place of the conventional ultraviolet light, electron beams (e-beams), excimer laser beams, EUV, BEUV and X-rays are used as the short wavelength actinic rays. Needless to say the minimum size obtainable is, in part, determined by the performance of the resist material and, in part, the wavelength of the actinic rays. Various materials have been proposed as suitable resist materials. For example, in the case of negative tone resists based on polymer crosslinking, there is an inherent resolution limit of about 10 nm, which is the approximate radius of a single polymer molecule.

It is also known to apply a technique called “chemical amplification” to resist materials. A chemically amplified resist material is generally a multi-component formulation in which there is a matrix material, frequently a main polymeric component, such as a polyhydroxystyrene (PHOST) resin protected by acid labile groups and a photo acid generator (PAG), as well as one or more additional components which impart desired properties to the resist. The matrix material contributes toward properties such as etching resistance and mechanical stability. By definition, the chemical amplification occurs through a catalytic process involving the PAG, which results in a single irradiation event causing the transformation of multiple resist molecules. The acid produced by the PAG reacts catalytically with the polymer to cause it to lose a functional group or, alternatively, cause a crosslinking event. The speed of the reaction can be driven, for example, by heating the resist film. In this way the sensitivity of the material to actinic radiation is greatly increased, as small numbers of irradiation events give rise to a large number of solubility changing events. As noted above, chemically amplified resists may be either positive or negative working.

Certain chemically amplified resists do not use large polymers. In cases where nanometer-scale patterning is desired, low molecular weight polymers or even small molecules may be used as the resist matrix material. These are sometimes referred to as “molecular glass” resists (MGRs), taken in this instance to include molecules such as oligomers, polyaromatic hydrocarbon derivatives, discotic liquids crystals, fullerenes, macrocycles, small amorphous, and other low molecular weight resists. Although MGRs may offer many potential advantages over polymeric chemically amplified resists, there are still some things about this class of materials that could potentially pose challenges. Removal and subsequent volatilization of protecting groups in positive tone molecular resists may cause a loss of up to approximately 50% of the mass of the resist, potentially leading to a loss of pattern quality. The small sizes of molecular resist compounds, and often correspondingly low glass transition temperatures, can also restore material integrity but may compromise pattern quality.

As the requirement for feature size continues to be reduced, below 20 nm for example, there is a need to control the cationic polymerization and/or crosslinking, in negative working systems. Photoresists based on acid catalyzed deprotection such as in positive working systems, utilize base quenchers which controls the migration of the photoacid to areas where deprotection is not desired. Typical epoxy-based negative working photoresists are initiated by photo-generated acid, but the active polymerization and crosslinking species are not photoacids. (See FIG. 1). It can readily be seen that after initial reaction of the epoxy, or other group, such as, for example, an acid-labile protecting group, the process involves the photoacid protonation of the epoxy oxygen to provide an 0 intermediate. However, after this initiating stage, the reaction continues by attack of the epoxonium intermediate by an oxygen of a neutral epoxy group. Propagation, polymerization and/or crosslinking then continues until termination. In these photopattern processes, controlling the polymerization and/or crosslinking becomes important to prevent line growth, or sharpening, and polymer growth in areas which are undesirable. These undesirable characteristics of conventional photopatterning processes include line edge roughness, line wiggle and other less than desirable pattern geometries. These characteristics are particularly critical in line and spaces less than 20 nm. Thus, any methods that will control the polymerization and/or crosslinking in photosystems to result in less undesirable geometries, such as for example, during EUV exposure, is highly desirable.

### DESCRIPTION OF THE DRAWINGS

FIG. 1 illustrates the reaction of epoxy materials to acid including initiation and propagation.

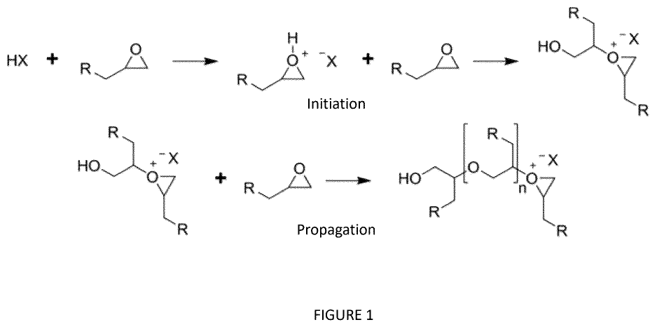

FIG. 2 illustrates the zwitterionic portion of the materials disclosed and claimed in this disclosure.

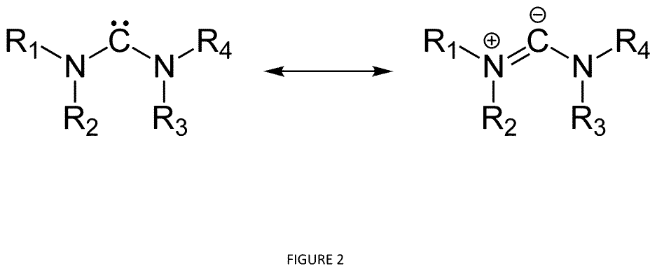

FIG. 3 illustrates the pathways by which it is believed the materials of the current disclosure benefit obtaining nano-sized lines and spaces of the photoresist into which they are formulated with minimal line width roughness.

FIG. 4 shows SEMs of the geometries and line edge roughness obtainable from a photoresist containing a zwitterion of the current disclosure.

FIG. 5 shows SEMs of the geometries and line edge roughness obtainable from photoresists containing other zwitterions of the current disclosure.

### DETAILED DESCRIPTION OF THE DISCLOSURE

As used herein, the conjunction “and” is intended to be inclusive and the conjunction “or” is not intended to be exclusive unless otherwise indicated or required by the context. For example, the phrase “or, alternatively” is intended to be exclusive. As used herein, the term “exemplary” is intended to describe an example and is not intended to indicate preference. As used herein, the term “energetically accessible” is used to describe products that may be thermodynamically or kinetically available via a chemical reaction.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

We have surprisingly found that the addition of certain, stable dipole materials to either positive or negative resists, improve the geometries and integrity of lines and spaces after EUV exposure and processing, such as, for example, improvements in line edge roughness, line wiggle, undercutting, bridging, line collapse, and the like.

As used herein, the term “dipole” means a molecule which contains both a positive charge center and a negative charge center on the same molecule, either alpha to each other or spaced further in the molecule. Further as used herein, the term “dipole” refers to zwitterions, betaines, ylides, and mesoionic compounds described below and is not meant to mean any one particular molecule but a representative molecule of the group.

A zwitterion, also called an inner salt, is a molecule that contains an equal number of positively and negatively charged functional groups. Amino acids are an example wherein there is a chemical equilibrium between the parent molecule and the zwitterion.

Disclosed and claimed herein are photolithographic compositions containing the zwitterion compounds (1) shown below.

As mentioned, the use of base quenchers has been used in positive working systems where initiation and propagation are reliant on the photogenerate acid. In the negative systems of the current disclosure photogenerated acid function to initiate the curing process, while further polymerization and/or crosslinking does not depend on the acid. Thus, base quenchers only have a very limited effect in the current systems.

We have found a group of materials that act as “molecular switches”.

Not to be held to theory, it is believed that the zwitterionic compounds of the current disclosure interfere with the stray propagation of polymerization in negative photoresists resulting in improved structural integrity of the desired resist geometries; and in positive photoresists, it is believed that the zwitterionic compounds of the current disclosure interfere with extraneous deprotection processes preventing developer attack. These stable anions, when acting as acid quenchers to become protonate species with pKa's approximately 13. As such they are approximately 2 orders of magnitude, or 100 times, less acidic that the typical protonated secondary amines

Further, not to be held to theory it is believed that the zwitterionic materials of the current disclosure act as an acid buffer in regions of high light/radiation intensity. The term buffering as used herein refers to the interaction of the betaine or ylide additive with a photogenerated acid.

In exposures based on Extreme UV, where many H+ atoms are generated (via photoelectron generation) such buffering appears to improve the structure, definition and integrity of photolithographically created patterns.

In regions of high exposure, it is believed that the zwitterionic materials of the current disclosure component of the photoresist reacts with the high levels of photogenerated acid which then reacts with the polymerization and/or crosslinking components of the resist, in this example, the epoxy components.

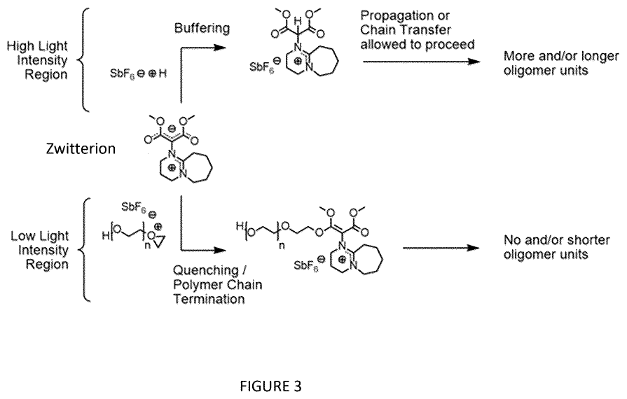

In regions of low exposure or where there is acid migration, where low levels of photogenerated acid occurs, the zwitterionic materials of the current disclosure component act as a quencher, stopping polymerization and/or crosslinking, from moving into unexposed regions preventing undesirable photopattern structures (FIG. 3)

Research has shown that the zwitterionic materials of the current disclosure as components of photoresists, especially in EUV resists, of the current disclosure increase contrast and reduce LER due their quenching properties. We believe that the zwitterionic materials of the current disclosure act as chain transfer agents during polymerization of the photosensitive composition. Further we believe that the zwitterionic materials of the current disclosure acts as a quencher which stops polymerization of the photosensitive composition from migrating into unexposed areas.

In high light intensity regions, the zwitterionic materials of the current disclosure that has already been used as a buffer can no longer act as a quencher. Where the zwitterionic materials of the current disclosure has already been used as a buffer, propagation or chain transfers (the mechanisms of polymerization) will proceed as is desired. The zwitterionic materials of the current disclosure may be acting as a very effective molecular switch.

In the current disclosure other additives are contemplated that act as molecular switches wherein exposure of the switch to actinic radiation causes a change in the molecule's configuration, electronic structure or other characteristic that may allow for buffering, chain propagation and termination.

In various aspects of the current disclosure, additives which are zwitterion synthons are contemplated. When these synthons, present in the photolithographic formulations, are exposed to radiation, such as, for example, I-line or EUV, they become zwitterions useful as buffers, chain propagators, chain transfer agents, and/or molecular switches.

Disclosed and claimed herein is a composition of matter, comprising an ester, wherein the ester is product of a chemical reaction between a malonate ester and an imidamide in the presence of a suitable halogen donor or pseudohalogen donor.

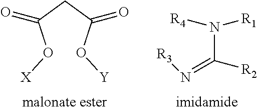

wherein X and Y are the same or different, wherein X, Y and R₁-R₄ and are branched or unbranched, substituted or unsubstituted alkyl chains of 1-24 carbon atoms having 0-16 heteroatoms substituted into the chain, are substituted or unsubstituted phenyl groups, heteroaromatic groups, or fused aromatic or fused heteroaromatic groups or combinations of both.

Further disclosed herein is a composition of matter produced by the above chemical reaction wherein R₁ and R₂ are conjoined by a chemical bond to form a ring structure having 5-8 members, and wherein R₃ and R₄ are conjoined by a chemical bond to form a ring structure having 5-8 members.

Still further disclosed herein is a composition of matter, wherein the imidamide comprises a fused ring structure as shown:

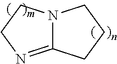

wherein m=1-4 and n=1-4.

Further disclosed herein is a composition of matter comprising a solvent; and an ester having a chemical structure (I):

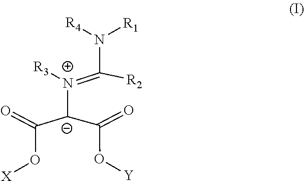

wherein X and Y are the same or different, wherein X, Y and R₁-R₄ and are branched or unbranched, substituted or unsubstituted alkyl chains of 1-24 carbon atoms having 0-16 heteroatoms substituted into the chain, are substituted or unsubstituted phenyl groups, heteroaromatic groups, or fused aromatic or fused heteroaromatic groups or combinations of both.

Further disclosed herein is a composition of matter comprising: a solvent; and an ester having a chemical structure chosen from (XII),

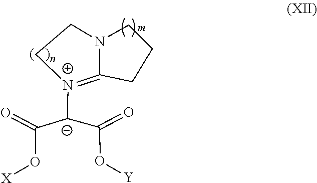

wherein X and Y are the same or different, wherein X, Y and R₁-R₄ and are branched or unbranched, substituted or unsubstituted alkyl chains of 1-24 carbon atoms having 0-16 heteroatoms substituted into the chain, are substituted or unsubstituted phenyl groups, heteroaromatic groups, or fused aromatic or fused heteroaromatic groups or combinations of both.

In the above disclosed structures, it is also contemplated that tautomers and other resonance structures may also be energetically available. The structures, disclosed supra, are therefore intended to include tautomers and other resonance structures. For example:

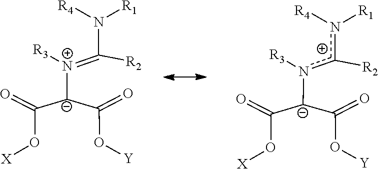

wherein X and Y are the same or different, wherein X, Y and R₁-R₄ and are branched or unbranched, substituted or unsubstituted alkyl chains of 1-24 carbon atoms having 0-16 heteroatoms substituted into the chain, are substituted or unsubstituted phenyl groups, heteroaromatic groups, or fused aromatic or fused heteroaromatic groups or combinations of both.

In addition, X and Y may comprise, for example, without limitation, no extender chain, or divalent extender chains comprising -alkyl-, -aryl-, -alkyl-aryl-, -aryl-alkyl-, -alkoxy-, -alkoxy-aryl-, -aryl-alkoxy-, -alkyl-alkoxy-, -alkoxy-alkyl-, or combinations of the foregoing.

More specifically, the -alkyl- group, above, can be a branched or unbranched divalent alkyl chain of 1-16 carbons with or without heteroatoms substituted into the chain, such as, for example, —CH2—, —CH2CH2—, —CH(CH3)CH2—, —CH2CH2CH2—, —CH2CH2CH2CH2—, butylene isomers, and the higher analogs up to and including hexadecylene, as well as their isomers. As used herein -alkyl- also includes any unsaturations in the chain such an olefin group, such as for example, —CH═CH—, or an alkynyl group. As mentioned the -alkyl- group may have heteroatoms substituted into the chain as part or the chain, such as O, N, S, S═O or SO2 and the like, such as, for example, —(CH2CH2—O)_{z}— wherein z is between about 1 and about 16, or —(CH2CH2NH)_{w}— wherein w is between about 1 and about 16, and the like. In accordance with the description above, the group, -alkoxy- may comprise one or more branched or unbranched alkyl groups such as -ethoxy-, -propoxy- or -isopropoxy- groups, separated by oxygen atoms. Also included are branched alkyl groups that contain heteroatoms in the ring, such as, for example —(CH2CH2NR″)v- wherein R″ can be a branched or unbranched divalent alkyl chain of 1-16 carbons with or without heteroatoms substituted into the R″ chain.

-Aryl-, above, is a substituted or unsubstituted divalent aromatic group, such aromatic groups include, for example the phenylenes (—C6H4—), the fused divalent aromatic group, such as, for example, the naphthylenes (—C10H6—), the anthracenylenes (—C14H8—) and the like, as well as the heteroaromatic groups, such as, for example, the nitrogen heterocycles: pyridines, quinolines, pyrroles, indoles, pyrazoles, the triazines, and other nitrogen-containing aromatic heterocycles well known in the arts, as well as the oxygen heterocycles: furans, oxazoles and other oxygen-containing aromatic heterocycles, as well the sulfur containing aromatic heterocycles, such as, for example, thiophenes.

Photoresist materials comprise an ester material such as (I)-(II), which takes the place of at least a portion of the resin in a conventional photoresist, and a photoacid generator. The discussion below describes useful photoacid generators for this purpose.

The above-described compositions of matter may further comprise, in admixture, photoacid generators. Without limitation, these may include onium salt compounds, such as sulfonium salts, phosphonium salts or iodonium salts, sulfone imide compounds, halogen-containing compounds, sulfone compounds, ester sulfonate compounds, quinone diazide compounds, diazomethane compounds, dicarboximidyl sulfonic acid esters, ylideneaminooxy sulfonic acid esters, sulfanyldiazomethanes, or a mixture thereof and other photoacid generators well known in the art.

Negative working materials may also comprise a crosslinker. Crosslinkers, suitable for the current disclosure, comprise compounds able to cross-link with the above disclosed ester, after it is deprotected, but, in any case, if either X or Y comprise functional groups that can be reacted with the crosslinker. Among these reactive functional groups are alcohols, phenols, protic amides, carboxylic acids and the like. Before the deprotection reaction occurs, at least a portion of the reactive functional groups are protected by an acid labile group described above. Once the deprotection reaction occurs, the crosslinker may react with the deprotected functional group. Not to be held to theory, it is believed that the photogenerated acid not only reacts with the acid-labile group of the above disclosed ester but aids in the reaction of the crosslinker with itself and the ester. Examples of crosslinkers include compounds comprising at least one type of substituted group that possess a cross-linking reactivity with the phenol or similar group of the on the deprotected ester. Specific examples of this crosslinking group include, without limitation, polymeric, oligomeric and monomeric materials containing an epoxy group, the glycidyl ether group, the oxetane group, glycidyl ester group, glycidyl amino group, methoxymethyl group, ethoxy methyl group, benzyloxymethyl group, dimethylamino methyl group, diethylamino methyl group, dimethylol amino methyl group, diethylol amino methyl group, morpholino methyl group, acetoxymethyl group, benzyloxy methyl group, formyl group, acetyl group, vinyl group and isopropenyl group.

Non limiting examples of compounds having the aforementioned cross-linking substituted group include, bisphenol A-based epoxy compounds, bisphenol F-based epoxy compounds, bisphenol S-based epoxy compounds, novolac resin-based epoxy compound, resol resin-based epoxy compounds, poly (hydroxystyrene)-based epoxy compounds, (3-ethyloxetan-3-yl)methanol, 1,3-bis(((3-ethyloxetan-3-yl)methoxy)methyl)benzene, 3,3′-oxybis(methylene)bis(3-ethyloxetane), and phenol novolak oxetane, sold by Toagosei America Inc. of West Jefferson, OH, as OXT-101, OXT-121, OXT-221 and PNOX1009, respectively, methylol group-containing melamine compounds, methylol group-containing benzoguanamine compounds, methylol group-containing urea compounds, methylol group-containing phenol compounds, alkoxyalkyl group-containing melamine compounds, alkoxyalkyl group-containing benzoguanamine compounds, alkoxyalkyl group-containing urea compounds, alkoxyalkyl group-containing phenol compounds, carboxymethyl group-containing melamine resins, carboxy methyl group-containing benzoguanamine resins, carboxymethyl group-containing urea resins, carboxymethyl group-containing phenol resins, carboxymethyl group-containing melamine compounds, carboxymethyl group-containing benzoguanamine compounds, carboxymethyl group-containing urea compounds, and carboxymethyl group-containing phenol compounds, methylol group-containing phenol compounds, methoxymethyl group-containing melamine compounds, methoxymethyl group-containing phenol compounds, methoxymethyl group-containing glycol-uril compounds, methoxymethyl group-containing urea compounds and acetoxymethyl group-containing phenol compounds. The methoxymethyl group-containing melamine compounds are commercially available as, for example, CYMEL300, CYMEL301, CYMEL303, CYMEL305 (manufactured by Mitsui Cyanamid), the methoxymethyl group-containing glycol-uril compounds are commercially available as, for example, CYMEL117 4 (manufactured by Mitsui Cyanamid), and the methoxymethyl group-containing urea compounds are commercially available as, for example, MX290 (manufactured by Sanwa Chemicals).

A photosensitive composition comprising the above compositions of matter may further comprise a solvent to enable spin coating on a semiconductor, other device in process, or other work piece. Suitable solvents include ethers, esters, etheresters, ketones and ketoneesters and, more specifically, ethylene glycol monoalkyl ethers, diethylene glycol dialkyl ethers, propylene glycol monoalkyl ethers, propylene glycol dialkyl ethers, alkyl phenyl ethers such as anisole, acetate esters, hydroxyacetate esters, lactate esters, such as ethyl lactate, methyl lactate, propyl lactate, butyl lactate, ethylene glycol monoalkylether acetates, propylene glycol monoalkylether acetates, alkoxyacetate esters, (non-)cyclic ketones, acetoacetate esters, pyruvate esters and propionate esters. Specific examples of these solvents include ethylene glycol monomethyl ether, ethylene glycol monoethyl ether, ethylene glycol monopropyl ether, ethylene glycol monobutyl ether, diethylene glycol dimethyl ether, diethylene glycol diethyl ether, diethylene glycol dipropyl ether, diethylene glycol dibutyl ether, methylcellosolve acetate, ethyl cellosolve acetate, propylene glycol monomethyletheracetate, propylene glycol monoethyletheracetate, propylene glycol monopropyletheracetate, isopropenyl acetate, isopropenyl propionate, methylethyl ketone, cyclohexanone, 2-heptanone, 3-heptanone, 4-heptanone, 2-hydroxypropionate ethyl, 2-hydroxy-2-methylpropionate ethyl, ethoxy acetate ethyl, hydroxyacetate ethyl, 2-hydroxy-3-methyl methylbutyrate, 3-methoxybutylacetate, 3-methyl-3-methoxybutylacetate, 3-methyl-3-methoxybutyl propionate, 3-methyl-3-methoxybutyl butylate, ethyl acetate, propyl acetate, butyl acetate, methyl acetoacetate, ethyl acetoacetate, methyl 3-methoxypropionate, ethyl 3-methoxy propionate, 3-ethoxy propionate methyl and 3-ethoxy propionate ethyl. The aforementioned solvents may be used independently or as a mixture of two or more types. Furthermore, at least one type of high boiling point solvent such as benzylethyl ether, dihexyl ether, diethylene glycol monomethyl ether, diethylene glycol monoethyl ether, acetonylacetone, isoholon, caproic acid, capric acid, 1-octanol, 1-nonanol, benzyl alcohol, benzyl acetate, ethyl benzoate, diethyl oxalate, diethyl maleate, γ-butyrolactone, ethylene carbonate, propylene carbonate and phenylcellosolve acetate may be added to the aforementioned solvent. Other suitable solvents include the halogen solvents.

Various additives may be added to the photoresist formulations to provide certain desirable characteristics of the photosensitive composition such as, for example, acid diffusion control agents to retard acid from migrating into unexposed areas of the coating, surfactants and leveling agents to improve coating of substrates, adhesion promoters to improve adhesion of the coating to the substrate and sensitizers to improve the photosensitivity of the photosensitive composition coating during photoexposure, and antifoaming agents and air release agents, as well as other materials well known in the coatings industry.

Some photoresists may additionally encompass one or more optional components or additives in addition to the aforementioned composition of matter, photoacid generators and solvents. Such components include base quenchers. Suitable base quenchers include, but are not limited to, tetramethylammonium hydroxide, triethanolamine, triisopropylamine, N-methylpyrrolidone, 1,8-diazabicyclo[5.4.0]undec-7-ene (DBU), 1,5-diazabicyclo[4.3.0]non-5-ene (DBN), 7-Methyl-1,5,7-triazabicyclo(4.4.0)dec-5-ene, quinuclidine, carboxylate salts such as tetramethylammonium acetate, tetramethylammonium lactate, tetramethylammonium propanoate, and the like.

The photosensitive compositions can be coated onto substrate such as a silicon wafer or a wafer coated with silicon dioxide, aluminium, aluminum oxide, copper, nickel, any of a number of semiconductor materials or nitrides or other substrates well known the semiconductor industry, or a substrate having thereon an organic film, such as, for example, a bottom layer anti-reflective film or the like. The photoresist compositions are applied by such processes as spin coating, curtain coating, slot coating, dip coating, roller coating, blade coating, ultrasonic coating, vapor coating and the like. After coating, the solvent is removed, if applicable, to a level wherein the coating can be properly exposed, abd baked and developed, if applicable. In some cases a residual of 5% solvent may remain in the coating while in other cases less than 1% is required. Drying can be accomplished by hot plate heating, convection heating, infrared heating and the like. The coating is then imagewise exposed through a mark containing a desired pattern or flood exposed.

Radiation suitable for the described photosensitive compositions include, for example, ultraviolet rays (UV), such as the bright line spectrum of a mercury lamp (254 nm), a KrF excimer laser (248 nm), and an ArF excimer laser (193 nm), an F₂ excimer laser (157 nm), extreme ultraviolet (EUV) such as 13.5 nm from plasma discharge and synchrotron light sources, beyond extreme ultraviolet (BEUV) such as 6.7 nm exposure, X-ray such as synchrotron radiation. Ion beam lithography and charged particle rays such as electron beams may also be used.

Following exposure, the exposed coated substrate may optionally be post exposure baked to enhance the reaction of the generated photoacid, such as, for example, heating from about 30 to about 350° C. for about 10 to about 600 seconds. This may be accomplished by hot plate heating, convection heating, infrared heating and the like. The heating may also be performed by a laser heating processes such as, for example, a CO₂ laser pulse heating for about 2 to about 5 milliseconds. Both heating processes may be combined in tandem.

A flood exposure process may be applied after the pattern exposure to aid in further cure. Results have indicated that flood exposure reduces or eliminates pattern collapse after development of the negative-tone resists as well as reduction in line edge roughness. For example, a 532 nm continuous wave laser exposes the previously exposed resist for 1-2 sec followed by wet development. The flood process may or may not be followed by a heating step.

The exposed film is then developed using a suitable a developer. Such developers include organic solvents as well as aqueous solutions such as aqueous alkali solutions known in the art. When an organic solvent is used to remove the unexposed areas generally the solvent is less aggressive than the solvent that was used in preparing the photoresist composition. Examples of aqueous alkali development solution include, for example, at least one type of alkaline compound such alkali metal hydroxides, ammonia water, alkylamines, alkanolamines, heterocyclicamines, tetraalkyl ammonium hydroxides such as tetramethyl ammonium hydroxide, cholines, and 1,8-diazabicyclo[5.4.0]-7-undecan,1,5-diazabicyclo[4.3.0]-5-nonene at a concentration of about 1 to about 10% by weight, such as, for example, about 2 to about 5% by weight. Water-soluble organic solvents such as methanol and ethanol and surfactants may also be added in suitable amounts to the alkaline aqueous solution, depending on the desired development characteristics and process parameters.

After development a final baking step may be included to further enhance the curing of the now exposed and developed pattern. The heating process may be, for example, from about 30 to about 350° C. for about 10 to about 120 seconds and may be accomplished by hot plate heating, convection heating, infrared heating and the like.

### EXAMPLES

### 1) Synthesis Example 1

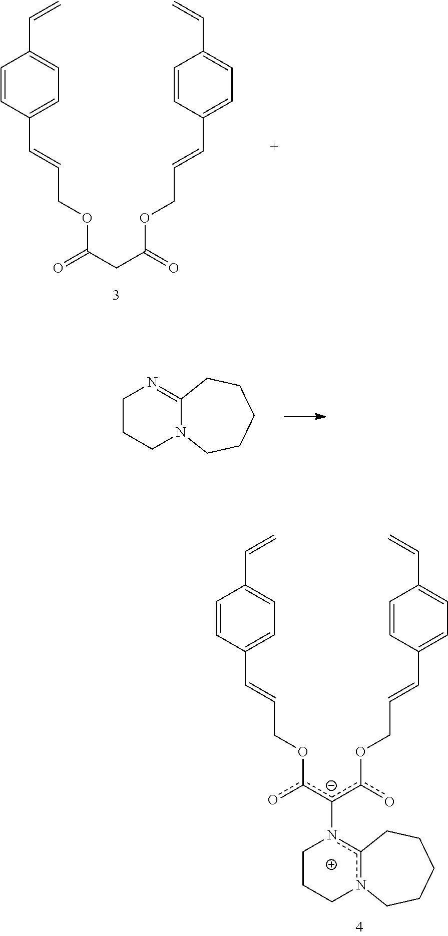

Tetrabromomethane (4.05 g, 12.2 mmol) and 3 (2.07 g, 11.0 mmol) were added to a 500 mL round bottom flask. Toluene (240 mL) was added, and the mixture was stirred under nitrogen for 1 hour. 1,8-Diazabicyclo[S.4.0]undec-7-ene (DBU, 7.3 g, 48.2 mmol) was added dropwise. The reaction mixture was stirred under nitrogen for 18 hours and then filtered. The resulting mixture was purified via a silica gel column using toluene, followed by ethyl acetate and then a gradient of 20% to 50% isopropanol/ethyl acetate. The product fraction was collected, and solvent was removed to give a 72% yield of the final product as a thick red-brown oil. The product was characterized by 1H NMR as compound 4.

### 2) Synthesis Example 2

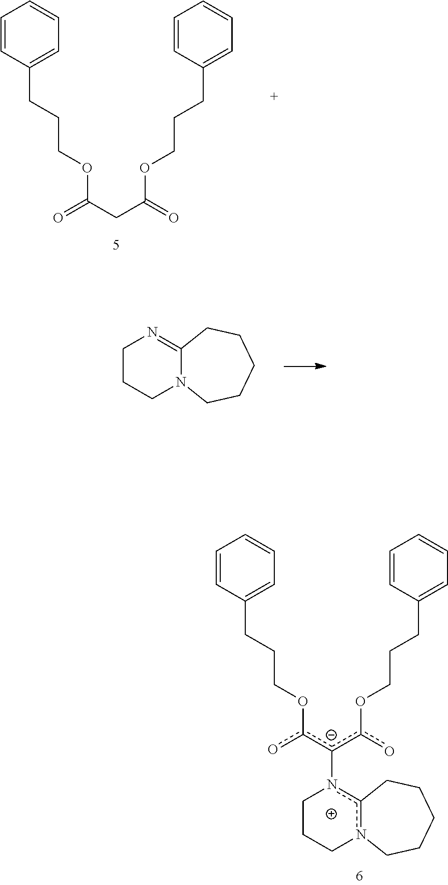

Tetrabromomethane (4.05 g, 12.2 mmol) and 5 (4.27 g, 11.0 mmol) were added to a 500 mL round bottom flask. Toluene (240 mL) was added and the mixture was stirred under nitrogen for 1 hour. 1,8-Diazabicyclo[S.4.0]undec-7-ene (DBU, 7.3 g, 48.2 mmol) was added dropwise. The reaction mixture was stirred under nitrogen for 18 hours and then filtered. The resulting mixture was purified via a silica gel column using toluene, followed by ethyl acetate and then a gradient of 20% to 50% isopropanol/ethyl acetate. The product fraction was collected and solvent was removed to give a 63% yield of the final product as a yellow solid. The product was characterized by 1H NMR as compound 6.

### 3) Synthesis Example 3

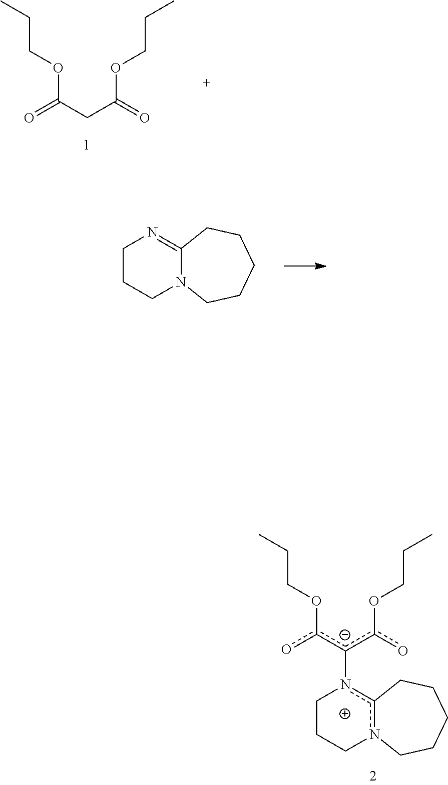

Tetrabromomethane (4.05 g, 12.2 mmol) and 1 (3.74 g, 11.0 mmol) were added to a 500 mL round bottom flask. Toluene (240 mL) was added and the mixture was stirred under nitrogen for 1 hour. 1,8-Diazabicyclo[S.4.0]undec-7-ene (DBU, 7.3 g, 48.2 mmol) was added dropwise. The reaction mixture was stirred under nitrogen for 18 hours and then filtered. The resulting mixture was purified via a silica gel column using toluene, followed by ethyl acetate and then a gradient of 20% to 50% isopropanol/ethyl acetate. The product fraction was collected and solvent was removed to give a 75.6% yield of the final product as a thick red-brown oil. The product was characterized by 1H NMR as compound 2.

### 4) Formulation Example 1

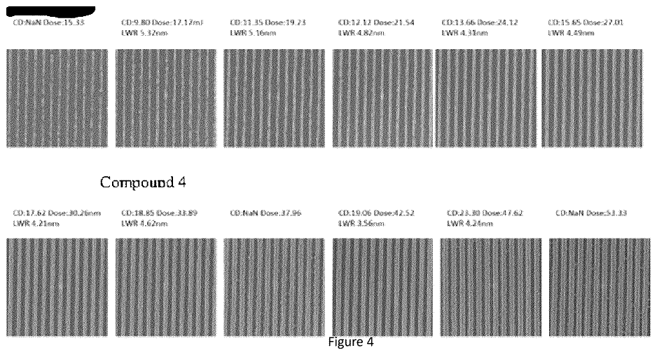

To 100 mL of ethyl lactate was added 0.128 g of 4, (the product synthesis example 1 above), 1.00 g of poly[(0-cresyl glycidyl ether)-co-formaldehyde](Mn=1270) and 0.461 g triphenylsulphonium hexafluoroantimonate and 0.09 g of triphenylsulphonium tosylate and stirred 1 hour at room temperature to give a 15 g./liter solution. The composition was applied to a silicon wafer prepared with 20 nm of Optistack AL412 underlayer). The underlayer was spun at 2000 rpm and baked at 205 C for 30 secs). The composition was spin-coated onto the wafer with undercoating at 500 rpm for 5 sec. followed by 1500 rpm for 90 sec. The coated wafer was then heated on a hot plate at 60° C. for 3 min to give a film approximately 20 nm thick. The wafer was imagewise exposed to E-beam at various increasing dosages through mask containing patterns of 44 nm pitch and post exposure baked at 60° C. for 1 min. The unexposed areas were removed by puddle development in n-butyl acetate for 30 sec followed by a methyl isobutyl ketone rinse. Results of this formulation are shown in FIG. 4.

As can be seen from the SEMs and Table 1 below, reduced line width roughness can be obtained by proper exposure for each critical dimension.

TABLE 1

| Critical Dimension (nm) | Exposure (mJ) | Line Width Roughness (nm) |
|---|---|---|
| NA | 15.33 | NA |
| 9.80 | 17.12 | 5.16 |
| 12.17 | 21.54 | 4.82 |
| 13.66 | 24.12 | 4.31 |
| 15.65 | 27.01 | 4.49 |
| 17.62 | 30.26 | 4.21 |
| 18.85 | 33.89 | 4.12 |
| NA | 37.96 | NA |
| 19.06 | 42.52 | 3.56 |
| 23.30 | 47.62 | 4.24 |
| NA | 53.33 | 5.33 |

### 5) Formulation Example 2

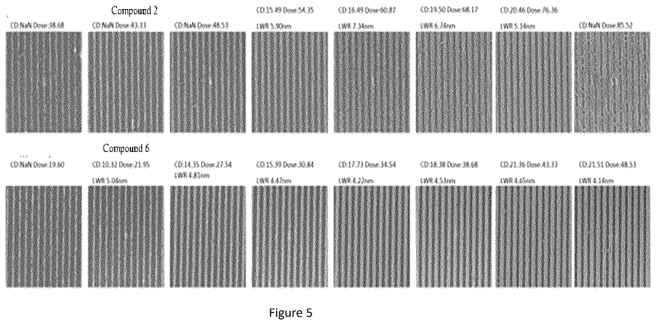

To 100 mL of ethyl lactate was added 0.15 g of 6, (the product synthesis example 2 above), 1.17 g of poly[(0-cresyl glycidyl ether)-co-formaldehyde](Mn=1270) and 0.54 g triphenylsulphonium hexafluoroantimonate and 0.10 g of triphenylsulphonium tosylate and stirred 1 hour at room temperature to give a 17.5 g./liter solution. The composition was applied to a silicon wafer prepared with 20 nm of Optistack AL412 underlayer. (The underlayer was spun at 2000 rpm and baked at 205° C. for 30 secs). The composition was spin-coated onto the wafer with undercoating at 500 rpm for 5 sec. followed by 2500 rpm for 90 sec. The coated wafer was then heated on a hot plate at 65° C. for 3 min to give a film approximately 17 nm thick. The wafer was imagewise exposed to E-beam at various increasing dosages through mask containing patterns of 44 nm pitch and post exposure baked at 65° C. for 1 min. The unexposed areas were removed by puddle development in n-butyl acetate for 60 sec. Results of this formulation are shown in FIG. 5, top and Table 2 below.

TABLE 2

| Critical Dimension (nm) | Exposure (mJ) | Line Width Roughness (nm) |
|---|---|---|
| NA | 38.68 | NA |
| NA | 43.77 | NA |
| NA | 48.53 | NA |
| 15.49 | 54.35 | 5.50 |
| 16.49 | 60.87 | 7.34 |
| 19.50 | 64.17 | 6.74 |
| 20.46 | 76.36 | 5.54 |
| NA | 85.52 | NA |

### 6) Formulation Example 3

To 100 mL of ethyl lactate was added 0.128 g of 2, (the product synthesis example 3 above), 1.00 g of poly[(0-cresyl glycidyl ether)-co-formaldehyde](Mn=1270) and 0.50 g triphenylsulphonium hexafluoroantimonate and 0.09 g of triphenylsulphonium tosylate and stirred 1 hour at room temperature to give a 15.0 g./liter solution. The composition was applied to a silicon wafer prepared with 20 nm of Optistack AL412 underlayer. (The underlayer was spun at 2000 rpm and baked at 205° C. for 30 secs). The composition was spin-coated onto the wafer with undercoating at 500 rpm for 5 sec. followed by 2500 rpm for 90 sec. The coated wafer was then heated on a hot plate at 65° C. for 3 min to give a film approximately 16 nm thick. The wafer was imagewise exposed to E-beam at various increasing dosages through mask containing patterns of 44 nm pitch and post exposure baked at 65° C. for 1 min. The unexposed areas were removed by puddle development in n-butyl acetate for 60 sec. Results of this formulation are shown in FIG. 5, bottom and Table 3 below.

TABLE 3

| Critical Dimension (nm) | Exposure (mJ) | Line Width Roughness (nm) |
|---|---|---|
| NA | 29.60 | NA |
| 10.32 | 21.95 | 5.04 |
| 14.35 | 27.54 | 4.83 |
| 15.39 | 30.84 | 4.47 |
| 17.73 | 34.54 | 4.22 |
| 14.28 | 38.68 | 4.53 |
| 21.36 | 43.33 | 4.64 |
| 21.51 | 48.53 | 4.24 |

We claim:

1. A composition of matter comprising a solvent; and an ester having a chemical structure (I), 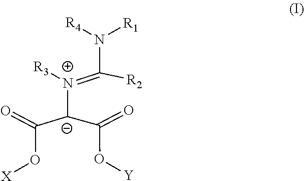
wherein X, Y and R₁-R₄ and are branched or unbranched, substituted or unsubstituted alkyl chains of 1-24 carbon atoms having 0-16 heteroatoms substituted into the chain, are substituted or unsubstituted phenyl groups, heteroaromatic groups, or fused aromatic or fused heteroaromatic groups or combinations of both.

2. The composition of matter of claim 1, further comprising, in admixture, one or more photoacid generators chosen from a sulfonium salt, an iodonium salt, a sulfone imide, a halogen-containing compound, a sulfone compound, an ester sulfonate compound, a diazomethane compound, a dicarboximidyl sulfonic acid ester, an ylideneaminooxy sulfonic acid ester, a sulfanyldiazomethane, or a mixture thereof.

3. The composition of matter of claim 2, further comprising at least one crosslinker, wherein the at least one crosslinker comprises an acid sensitive monomer or polymer, and wherein the at least one crosslinker comprises at least one of a glycidyl ether, a glycidyl ether of novolac resin, glycidyl ester, glycidyl amine, a methoxymethyl group, an ethoxy methyl group, a butoxymethyl group, a benzyloxymethyl group, dimethylamino methyl group, diethylamino methyl group, a dibutoxymethyl group, a dimethylol amino methyl group, diethylol amino methyl group, a dibutylol amino methyl group, a morpholino methyl group, acetoxymethyl group, benzyloxy methyl group, formyl group, acetyl group, vinyl group or an isopropenyl group.

4. The composition of matter of claim 3, wherein the composition is a photoresist sensitive to ultraviolet (UV), deep UV, vacuum UV, extreme UV, beyond EUV (BEUV), x-rays, electron beams and ion beams.

5. A composition of matter comprising: a solvent; and an ester having a chemical structure chosen from (IV): 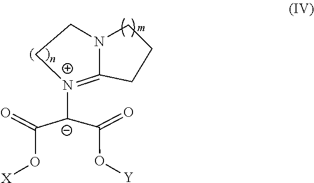
wherein m=1-4, n=1-4, and wherein X and Y are the same or different and are branched or unbranched, substituted or unsubstituted alkyl chains of 1-24 carbon atoms having 0-16 heteroatoms substituted into the chain, are substituted or unsubstituted phenyl groups, heteroaromatic groups, or fused aromatic or fused heteroaromatic groups or combinations of both.

6. The composition of matter of claim 5, wherein m=2 and n=3.

7. The composition of matter of claim 6, further comprising, in admixture, one or more photoacid generators chosen from a sulfonium salt, an iodonium salt, a sulfone imide, a halogen-containing compound, a sulfone compound, an ester sulfonate compound, a diazomethane compound, a dicarboximidyl sulfonic acid ester, an ylideneaminooxy sulfonic acid ester, a sulfanyldiazomethane, or a mixture thereof.

8. The composition of matter of claim 7, further comprising at least one crosslinker, wherein the at least one crosslinker comprises an acid sensitive monomer or polymer, and wherein the at least one crosslinker comprises at least one of a glycidyl ether, a glycidyl ether of a novolac resin, glycidyl ester, glycidyl amine, a methoxymethyl group, an ethoxy methyl group, a butoxymethyl group, a benzyloxymethyl group, dimethylamino methyl group, diethylamino methyl group, a dibutoxymethyl group, a dimethylol amino methyl group, diethylol amino methyl group, a dibutylol amino methyl group, a morpholino methyl group, acetoxymethyl group, benzyloxy methyl group, formyl group, acetyl group, vinyl group or an isopropenyl group.

9. The composition of matter of claim 8, wherein the composition is a photoresist sensitive to ultraviolet (UV), deep UV, vacuum UV, extreme UV, x-rays, electron beams and ion beams.
